(19) United States
(12) Patent Application Publication
(10) Pub. No.: US 2011/0074396 A1
(43) Pub. Date: Mar. 31, 2011

(54) BIOSENSOR AND ELECTRODE STRUCTURE THEREOF

(76) Inventors: Lun-De Liao, Hsinchu (TW); Yu-Han Chen, Hsinchu (TW); Paul C.-P. Chao, Hsinchu (TW); Chin-Teng Lin, Hsinchu (TW); Arch Sun, Hsinchu (TW); Shia-Chung Chen, Hsinchu (TW); Ming-Hsiu Chung, Hsinchu (TW)

(21) Appl. No.: 12/604,984

(22) Filed: Oct. 23, 2009

(30) Foreign Application Priority Data
Sep. 25, 2009 (TW) 98132506

(51) Int. Cl. G01R 13/20; H01B 5/00

(52) U.S. Cl. 324/121 R; 174/126.1

(57) ABSTRACT

An electrode structure of a biosensor includes a flexible conductive substrate and a plurality of conductive probes protruding from the conductive substrate and configured for contacting a subject and receiving a physiological electric wave signal therefrom. The present invention improves disadvantages of wet electrodes and microstructure electrodes and provides more stable signals that may less decay with time so as to achieve real-time and long-acting measurement for physiological electric wave signal. A biosensor using the electrode structure is also disclosed.

### BACKGROUND OF THE INVENTION

1. Field of the Invention

The present invention relates to a biosensor and an electrode structure thereof, more particularly to a biosensor and an electrode structure thereof having a flexible conductive substrate and a plurality of conductive probes.

2. Description of the Prior Art

The electric wave signal measurement has been widely applied in many fields such as military, biomedicine and man-machine systems and is used for measuring EEG (electroencephalography), ECG (electrocardiography), EMG (electromyography), etc. in biomedicine field. Conventional electric wave signal measuring instruments usually adopt wet electrodes, which require conducting gel for proper function. However, the conducting gel may cause illness of patients, e.g. allergy or swelling, and can not be long-acting since the conductivity thereof would decrease with time.

Dry electrodes have been recently developed to resolve the aforementioned problems of wet electrodes. However, the signal quality for dry electrodes is quite unstable, which needs to be improved for the dry electrodes to perform optimally.

However, most dry electrodes are made by microstructure process, e.g. MEMS (Micro Electro Mechanical Systems), or CNTs (carbon nanotubes), making them fragile and not suitable for area with hair. Due to these severe flaws mentioned above, the dry electrodes are not widely applied and the wet electrodes are still the mainstream product.

Since studies related to the biomedicine field have recently been highly regarded, and the improvements and applications in EEG and ECG instruments have also been continuously introduced, the instruments are now expected to be shrunk in size and achieve real-time and long-acting measurement.

Therefore, it is highly desirable to develop novel dry electrodes to replace wet electrodes and microstructure electrodes and to achieve real-time and long-acting measurement.

### SUMMARY OF THE INVENTION

The present invention is directed to provide a biosensor and an electrode structure thereof, so as to improve drawbacks of conventional wet electrodes and dry microstructure electrodes and provide more stable signals that may less decay with time so as to achieve real-time and long-acting measurement for physiological electric wave signal.

According to an embodiment of the present invention, an electrode structure of a biosensor includes a flexible conductive substrate and a plurality of conductive probes protruding from the conductive substrate and configured for contacting a subject and receiving a physiological electric wave signal therefrom.

According to another embodiment of the present invention, a biosensor includes at least one electrode structure and an oscilloscope. The electrode structure includes a flexible conductive substrate and a plurality of conductive probes protruding from the conductive substrate and configured for contacting a subject for receiving a physiological electric wave signal. The oscilloscope is electrically connected to the electrode structure and configured for displaying the physiological electric wave signal.

Other advantages of the present invention will become apparent from the following descriptions taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed descriptions, when taken in conjunction with the accompanying drawings, wherein:

FIG. 1 is a 3D diagram illustrating an electrode structure according to one embodiment of the present invention;

FIG. 2 is a 3D diagram illustrating an electrode structure according to another embodiment of the present invention;

FIG. 3 is a sectional view diagram illustrating the preparation method of the cushioning material according to another embodiment of the present invention;

FIG. 4 is a 3D diagram illustrating an electrode structure according to one embodiment of the present invention; and

FIGS. 5-6 are schematic diagrams illustrating experimental results of an electrode structure according to one embodiment of the present invention.

### DESCRIPTION OF THE PREFERRED EMBODIMENT

A biosensor used for measuring physiological electric wave signals generally includes at least one electrode structure and an oscilloscope. The electrode structure is configured for contacting a subject and receiving physiological electric wave signals, and the oscilloscope electrically connected to the electrode structure is configured for displaying the physiological electric wave signals. The oscilloscope may adopt a common man-machine interface, e.g. LabView (Laboratory Virtual Instrument Engineering Workbench) software. There may be an amplifying circuit and/or a filtering device serially connected between the electrode structure and the oscilloscope, wherein the amplifying circuit may be used for amplifying the physiological electric wave signals, and the filtering device may be used for filtering noises in the physiological electric wave signals.

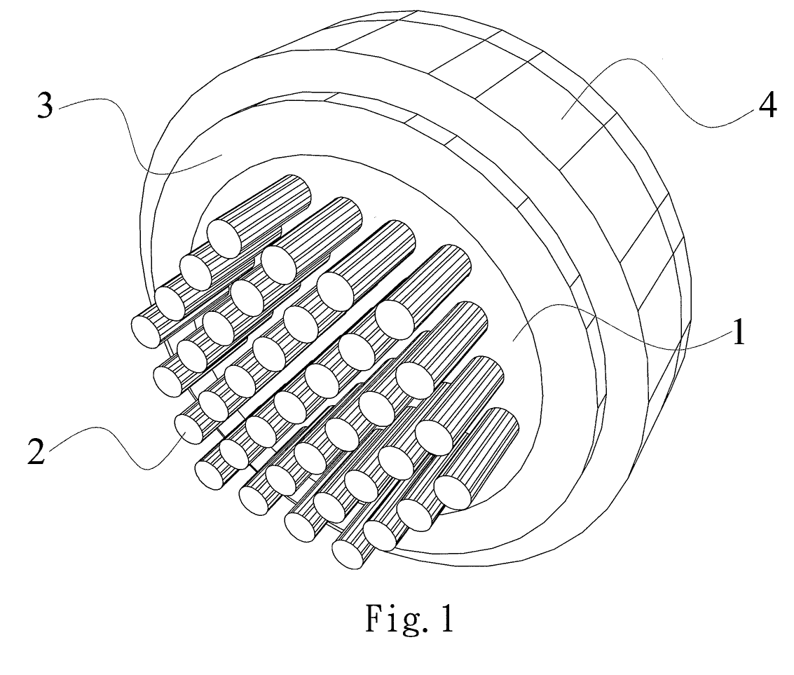

FIG. 1 is a 3D diagram illustrating an electrode structure of the present invention. The electrode structure includes a flexible conductive substrate 1 and a plurality of conductive probes 2 protruding from the conductive substrate 1. The conductive probes 2 are configured for contacting a subject and receiving physiological electric wave signals therefrom. The flexible conductive substrate 1 provides flexibility for the electrode structure to deform with the contour of the skin surface. The conductive probes 2 that protrude from the conductive substrate may be pillar-shaped or needle-shaped for contacting the skin surface to measure physiological electric wave signals. In the electrode structure of the present invention, all of the conductive probes 2 are electrically connected with the conductive substrate 1. Therefore, an electrode structure provides a measurement recorded as a single point, and when it is electrically connected with an oscilloscope, a physiological electric wave signal can be displayed.

Preferably, the conductive probes 2 and the conductive substrate 1 are made of metal, which generally includes without limitations to copper, iron, gold or silver.

Furthermore, the shape of the conductive probes 2 may be designed for desired effects. Still referring to FIG. 1, the conductive probes 2 adopted in the present invention resemble arrayed pins of an integrated circuit. Due to the small size and large quantity of conductive probes 2, the conductive probes 2 may provide good measuring results though being placed at an area with thick hair. Here, the above-mentioned electrode structure may be manufactured by stamping process, providing advantages of smaller size and relatively higher density in the same area.

The flexibility of the conductive substrate 1 may be achieved with the use of flexible material and/or by decreasing the thickness, and the preferred example is a sheet metal. In one example, the conductive substrate 1 may adopt a sheet metal with about 1 mm thickness. The sheet metal may have holes and each of the conductive probes 2 has a base portion connected to the conductive substrate 1 and a top portion contacting the skin of the subject. Here, the holes of the sheet metal may be the same as or a little bit smaller than the top portion of the conductive probes 2, allowing the conductive probes 2 to be pressed through the sheet metal during assembly. Also, the base portion is wider than the top portion of the conductive probes 2 so that the conductive probes 2 are retained to the conductive substrate 1. The electrode structure of the present invention is thus formed with all the conductive probes being pressed through and fixed to the sheet metal by stamping.

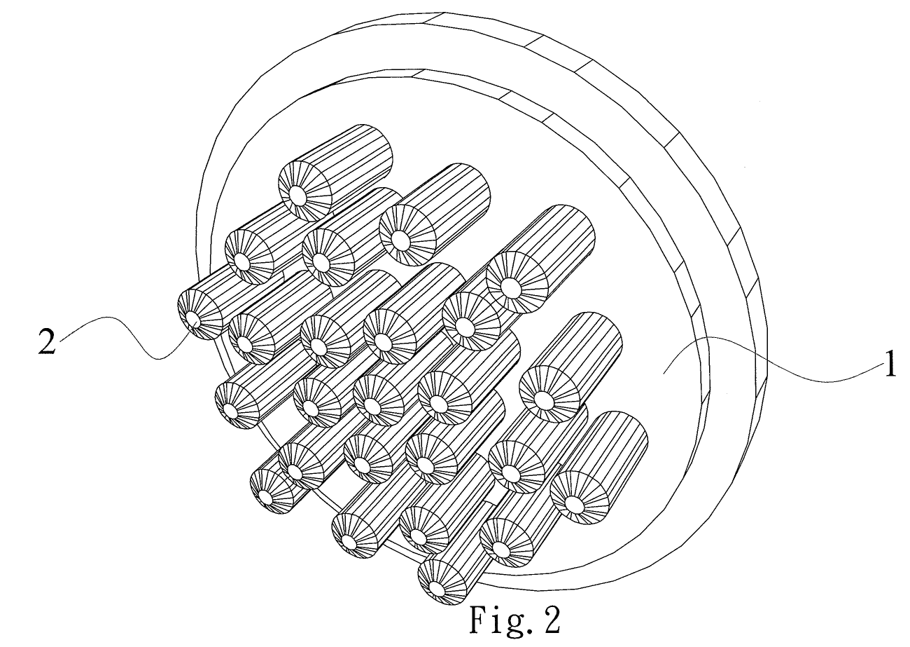

The electrode structure of the present invention has no limitations in size or shape. As illustrated in FIG. 2, in one embodiment, the conductive substrate 1 and the conductive probes 2 may be integrally molded and the shape of conductive probes 2 is relatively wider. In addition, in one example used for measuring human physiological electric wave signals, the electrode structure illustrated in FIG. 1 adopts the conductive substrate 1 with a diameter of about 25 mm, and the conductive probes 2 with a diameter of about 1 mm and a height of 15 mm; and the electrode structure illustrated in FIG. 2 adopts the conductive substrate 1 with a diameter of about 30 mm, and the conductive probes 2 with a diameter of about 3 mm and a height of 6 mm.

In one embodiment, the electrode structure includes a conductive coating material overlaying the surface of the conductive probes. The conductive coating material, e.g. gold or silver, may enhance conduction and prevent allergic response of the skin.

Referring to FIG. 1, the electrode structure may further includes a cushioning material 3 covering the conductive substrate 1 and exposing a portion of the conductive substrate 1 for providing further flexibility for the electrode structure. The electrode structure therefore may be better attached to the skin surface for more precise measurement and may reduce stress and accompanied illness caused when placed on the skin surface of the subject.

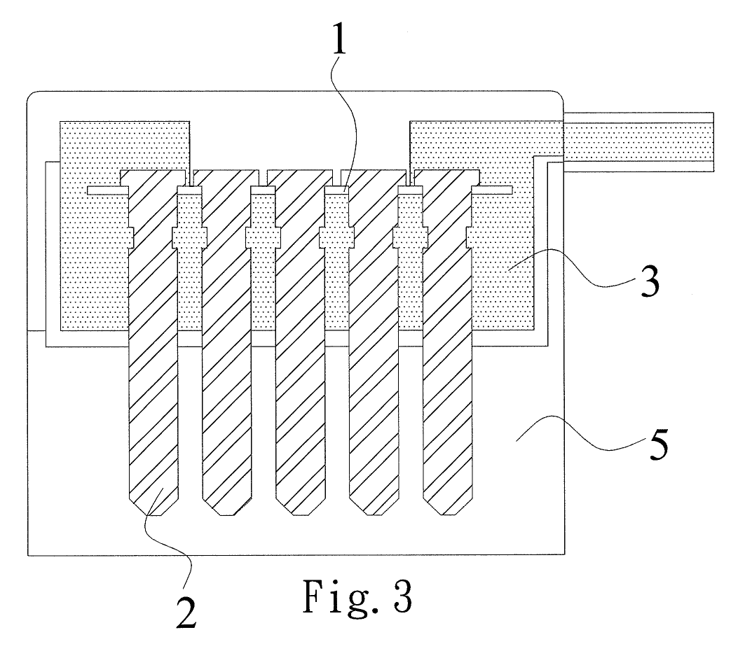

For example, the cushioning material 3 may be made of, without limitations to, silica gel, resin or plastic. FIG. 3 is a sectional view diagram illustrating the preparation method of the cushioning material. The cushioning material 3 may be prepared by injection molding. The joined conductive probes 2 and conductive substrate 1 are placed within the mold 5, and the melted cushioning material 3 is injected into the mold 5 by using a squeezer. After the cushioning material 3 is cooled and coagulated, the conductive probes 2 and conductive substrate 1 are covered with the molded cushioning material 3.

In addition, the cushioning material 3 may also achieve the function of fixing the conductive probes. As illustrated in FIG. 3, a portion of the conductive probes may be wrapped by the cushioning material 3 for fixation. In another embodiment, each of the conductive probes 2 may include a trench arranged between the base portion and the top portion. The trench may be filled with the cushioning material 3 by injection and molding for further fixing the conductive probes 2.

In one embodiment, the electrode structure is covered with a casing 4 for preventing from electrostatic charges and electromagnetic waves and for protecting the electrode structure. Preferably, the casing 4 includes an upper cover and a lower cover, which are detachable for the electrode structure arranged therein to be replaced. The whole electrode structure may be further fastened with other external mechanisms after placed into the anti-electrostatic casing 4.

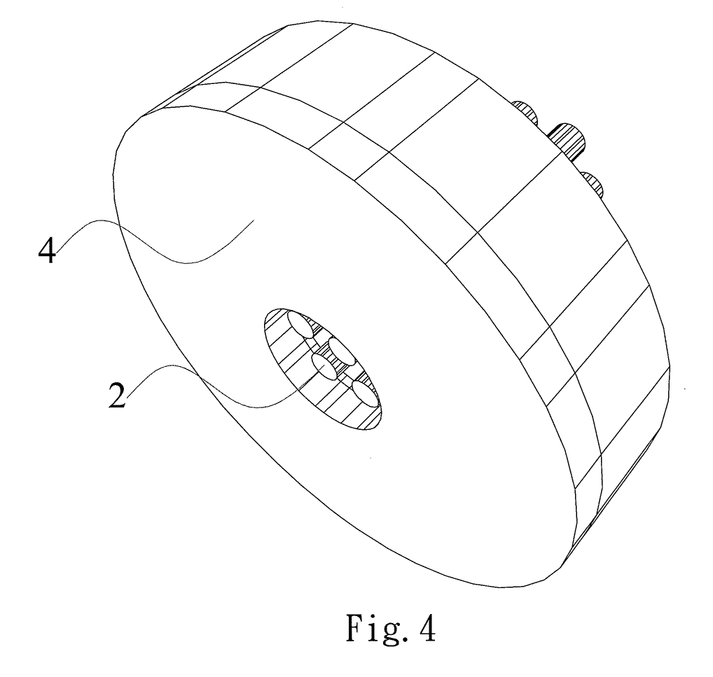

FIG. 4 is a side view diagram illustrating an electrode structure according to one embodiment of the present invention. Preferably, the casing 4 and the cushioning material 3 (not illustrated) expose a portion of the conductive substrate 1 (not illustrated) and the conductive probes 2 so that the electrode structure may be electrically connected to the oscilloscope for subsequent measurement.

Furthermore, in one embodiment, the electrode structure of the present invention may be disposable in consideration of improving personal hygiene and lowering the risk for infection. The internal cushioning material and conductive probes may be replaced. The electrode structure may be manufactured by stamping and injection molding to lower the cost for manufacturing.

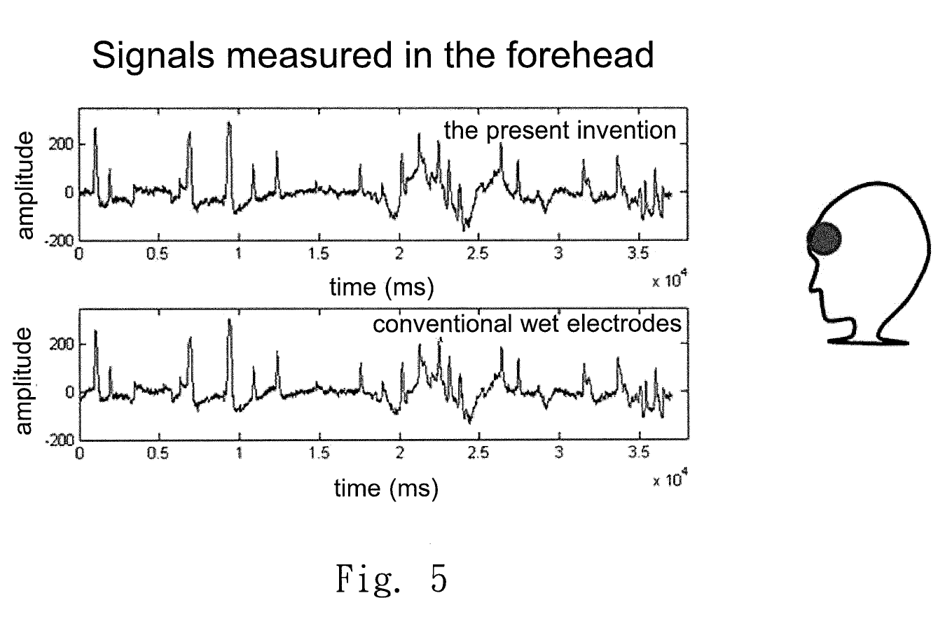

Experimental results measured with the electrode structure of the present invention are listed below. The results are compared with the control group measured with the conventional wet electrode. The measuring areas respectively include (1) the hairless forehead and (2) the side-head with hair. Referring to FIG. 5, for forehead measuring, the output signals of the experimental group and the control group resemble each other with a correlation coefficient of 0.95 calculated with MATLAB, where the output signals indicate many eye movements such as blinks, each represented by a peak.

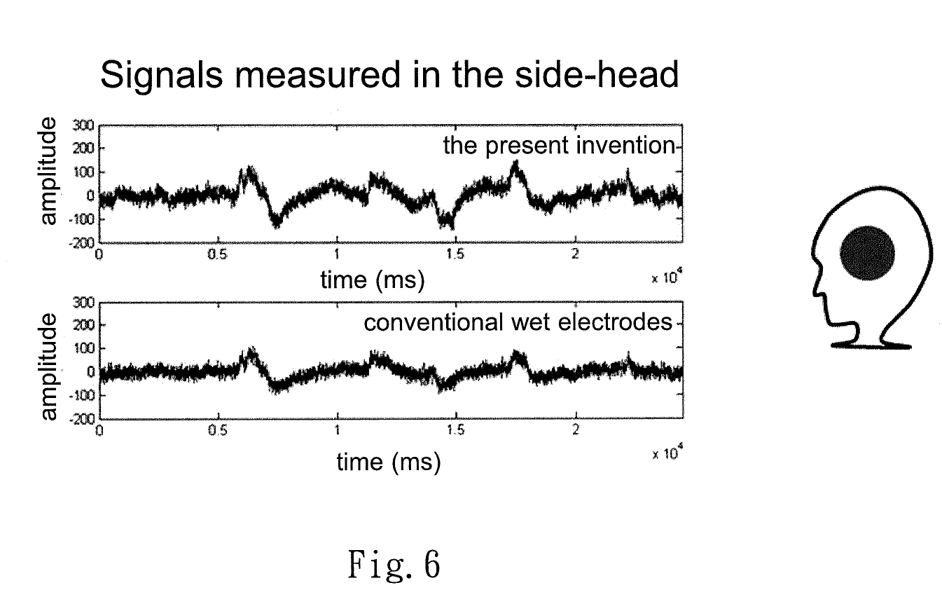

Referring to FIG. 6, for side-head measuring, the signals at this area have more noises due to hair and are less influenced by blinking. The output signals obtained by using the electrode structure of the present invention and the conventional wet electrode resemble each other with a correlation coefficient of 0.92 calculated with MATLAB. The experimental results validate that the electrode structure of the present invention may provide the same function in terms of output signals as the conventional wet electrode, and the electrode structure of the present invention is more convenient to use, however.

Some possible applications of the present invention are described below. As mentioned above, the biomedical electric wave signal measurement may include EEG (electroencephalography), ECG (electrocardiography), EMG (electromyography), and etc. The number of electrode structures may therefore vary with various applications and a signal from each electrode structure only represent one single point. For example, for an EEG measurement using 64-channel signals, 64 electrode structures are required. As for an ECG measurement using 3-channel signals, 3 electrode structures are required.

To sum up, the electrode structure of the present invention differs from conventional wet electrodes and dry microstructure electrodes and improves their drawbacks. The electrode structure of the present invention provides more stable signals that may less decay with time so as to achieve real-time and long-acting measurement for physiological electric wave signal.

While the invention can be subject to various modifications and alternative forms, a specific example thereof has been shown in the drawings and is herein described in detail. It should be understood, however, that the invention is not to be limited to the particular form disclosed, but on the contrary, the invention is to cover all modifications, equivalents, and alternatives falling within the spirit and scope of the appended claims.

What is claimed is:

1. An electrode structure of a biosensor, comprising:
a flexible conductive substrate; and
a plurality of conductive probes protruding from the conductive substrate and configured for contacting a subject and receiving a physiological electric wave signal therefrom.

2. The electrode structure as claimed in claim 1 further comprising:
a cushioning material covering the conductive substrate and exposing a portion of the conductive substrate.

3. The electrode structure as claimed in claim 2, wherein the cushioning material covers a portion of the conductive probes.

4. The electrode structure as claimed in claim 1, wherein the conductive substrate is made of metal.

5. The electrode structure as claimed in claim 1, further comprising:
a conductive coating material overlaying a surface of each of the conductive probes.

6. The electrode structure as claimed in claim 1, wherein the conductive probes are arranged in array.

7. The electrode structure as claimed in claim 1, wherein the conductive probes are pillar-shaped or needle-shaped.

8. The electrode structure as claimed in claim 1, wherein the conductive probes are made of metal.

9. The electrode structure as claimed in claim 1, wherein each of the conductive probes has a base portion connected to the conductive substrate and a top portion to be contacted with the subject, and the base portion is wider than the top portion.

10. The electrode structure as claimed in claim 9, wherein each of the conductive probes further includes a trench arranged between the base portion and the top portion.

11. A biosensor, comprising:
at least one electrode structure comprising
a flexible conductive substrate; and
a plurality of conductive probes protruding from the conductive substrate and configured for contacting a subject and receiving a physiological electric wave signal therefrom; and
an oscilloscope electrically connected to the electrode structure and configured for displaying the physiological electric wave signal.

12. The biosensor as claimed in claim 11, wherein the electrode structure further comprises a cushioning material covering the conductive substrate and exposing a portion of the conductive substrate.

13. The biosensor as claimed in claim 12, wherein the cushioning material covers a portion of the conductive probes.

14. The biosensor as claimed in claim 11 further comprising:
a casing covering the electrode structure and exposing a portion of the conductive probes.

15. The biosensor as claimed in claim 14, wherein the casing is detachable.

16. The biosensor as claimed in claim 11, wherein the conductive substrate is made of metal.

17. The biosensor as claimed in claim 11, wherein each of the electrode structure comprises a conductive coating material overlaying a surface of each of the conductive probes.

18. The biosensor as claimed in claim 11, wherein the conductive probes are arranged in array.

19. The biosensor as claimed in claim 11, wherein the conductive probes are pillar-shaped or needle-shaped.

20. The biosensor as claimed in claim 11, wherein the conductive probes are made of metal.

21. The biosensor as claimed in claim 11, wherein each of the conductive probes has a base portion connected to the conductive substrate and a top portion to be contacted with the subject, and the base portion is wider than the top portion.

22. The biosensor as claimed in claim 21, wherein each of the conductive probes further includes a trench arranged between the base portion and the top portion.

23. The biosensor as claimed in claim 11 further comprising:
an amplifying circuit serially connected between the electrode structure and the oscilloscope.

24. The biosensor as claimed in claim 11 further comprising:
a filtering device serially connected between the electrode structure and the oscilloscope.
